(19) United States
(12) Patent Application Publication
(10) Pub. No.: US 2024/0097055 A1
(43) Pub. Date: Mar. 21, 2024

(54) FOIL FOR USE WITH A DOUBLE CURVED SOLAR PANEL

(71) Applicant: Lightyear Layer IPCo B.V., Helmond (NL)

(72) Inventors: Durandus Kornelius DIJKEN, Eindhoven (NL); Hendrik Nicolaas SLINGERLAND, Venlo (NL)

(21) Appl. No.: 18/275,877

(22) PCT Filed: Feb. 15, 2022
(86) PCT No.: PCT/EP2022/053695

§ 371 Date: Aug. 4, 2023

(30) Foreign Application Priority Data
Feb. 17, 2021 (NL) 2027572

(51) Int. Cl. H01L 31/0216; B60L 1/00; H01L 31/05; H02S 30/10

(52) U.S. Cl. CPC H01L 31/02167; B60L 1/20; H01L 31/0516; H02S 30/10

(57) ABSTRACT

The invention relates to a foil (100) for a double curved solar panel, the foil showing multiple incisions having two closed ends and dividing the foil in mechanically interconnected areas, wherein the foil comprises a first group of incisions (102) having a first orientation and a second group of incisions (104) having a second orientation, a first closed end of the incision located at a mechanical interconnection (110) between a first cell (120) and a second cell (122) and a second closed end located at a mechanical interconnection (112) between a third cell (124) and a fourth cell (126), the incision bordered by a mechanical interconnection (114) between the first cell (120) and the third cell (124) and bordered by a mechanical interconnection (116) between the second cell (122) and the fourth cell (126), the incisions partly having a first orientation and partly having a second, different orientation.

### TECHNICAL FIELD OF THE INVENTION

The invention relates to a foil for use with a double curved solar panel, the foil showing a multitude of incisions having two closed endings, the incisions dividing the foil in a number of mechanically interconnected areas.

### ACKNOWLEDGEMENT

The project leading to this application has received funding from the European Union's Horizon 2020 research and innovation program under grant agreement No. 848620.

### BACKGROUND OF THE INVENTION

Nowadays more and more electric vehicles have a solar panel for generating electric power. Such panels, for example placed on, integrated with, or forming the roof of the vehicle, often show at least locally curvature in two directions. Also Building Integrated Photovoltaic Systems (BIPV systems) are often used on a 3-D curved surface (that is: a surface that is at least locally curved in two directions).

Electricity is generated by the solar cells, also known as photovoltaic cells. Typically the solar cells are polycrystalline or monocrystalline silicon cells, although cells from other materials, such as other semiconductors (for example doped GaAs), or yet other materials (such as perovskites) are known to be used. Also foils with a thin film of, for example, Copper indium gallium selenide (CIGS) or poly-crystalline silicon are known to be used. To avoid damage caused by chemicals or moisture, the cells or the thin film are typically encapsulated by an encapsulant.

The curved solar panel typically comprises a 3-D curved transparent plate (for example comprising glass or polycarbonate), solar cells encapsulated by an encapsulant bonded to the curved transparent plate, and conductors electrically interconnecting the solar cells in series (forming so-called strings) and/or in parallel. The interconnections can be made by so-called finger electrodes or by a back-contact foil (BCF) with metallization on one or two sides, the metallization (for example a thin layer of copper) being patterned.

Other such solar panels use a foil comprising thin film solar cells, for example a PET or polyimide foil with a perovskite printed or sprayed to it. This foil may be encapsulated in an encapsulant and is bonded to the transparent plate,

A problem arises when bonding a foil (encapsulated or not encapsulated) to a 3-D curved surface: wrinkles are likely to occur.

This problem is known from US patent application US20140130848A1 to Panasonic.

US20140130848A1 relates to a sheet of encapsulant comprising electrically interconnected solar cells, and describes in its FIGS. 3 and 5, and in the accompanying text, a foil or sheet divided by a number of parallel incisions in the encapsulant, the incisions dividing the encapsulant in a number of strips. The electrical interconnections between the solar cells are made using finger electrodes. Incisions are provided between serialized solar cells (the so-called strings) in a direction along the solar cell strings. The sheet of encapsulant, comprising the solar cells, is bonded to a transparent curved surface having three-dimensional curvature. Stress generated inside a surface of the solar cell sheet when the sheet is bonded along the curved surface of the transparent curved surface substrate can be alleviated by the incisions, and bonding can be performed while reducing twists and wrinkles occurring in the solar cell sheet.

The known application describes the effect when bonding a (cured) foil of encapsulant in a 3-D plane. Bonding a more rigid foil likely results in even more wrinkling.

Solar cells have a photosensitive side and a backside. Typically, first generation solar cells show one or more anodes located at one side and one or more cathodes at the other side. Cells are typically interconnected (in parallel or in series, or in a combination thereof) by so-called finger-electrodes. After making these interconnections the solar cells are sealed in an encapsulant. The slab manufactured in a flat plane, comprising the cells and the encapsulant, is then bonded to the curved transparent plate.

The interconnection between the solar cells is typically made while the solar cells are in one plane (in a non-curved situation). If a panel is flat, the cells in the encapsulant typically are arranged in a strictly rectangular array. If the panel is curved in two directions (thus showing having three-dimensional or short 3-D curvature) the array cannot be rectangular anymore due to the curvature.

A problem arises when bonding the flat foil to the curved transparent plane: wrinkles may occur in the foil.

The invention intends to provide an alternative solution to said limitation.

### SUMMARY OF THE INVENTION

To solve the before mentioned limitation the invention is characterized in that the foil comprises at least a first group of incisions having a first orientation and a second group of incisions having a second orientation, each of the incisions having two closed ends, a first closed end located at a mechanical interconnection between a first and a second cell and a second closed end located at a mechanical interconnection between a third and a fourth cell, the incision bordered by a mechanical interconnection between the first and the third cell and bordered by a mechanical interconnection between the second and the fourth cell, the incisions partly having a first orientation and partly having a second orientation, the first orientation different from the second orientation.

By having incisions in at least two different orientations, the incisions ending at the mechanical interconnection of cells and also bordered by mechanical interconnections, each incision can widen by a slight rotation of the further rigid areas. In this way the foil resembles an auxetic material, and a stretching in one direction (orientation) results in a stretching in another direction (orientation) as well. In this way a foil with, for example, a rectangular shape/boundary, can, without changing its outer boundary, curve in the central area of the foil.

It is noted that another group of incisions may be present that shows only one closed ending, the other end intersecting the boundary of the foil. These incisions enable the boundary of the foil to deform (curve) as well.

In an embodiment the incisions are straight incisions and the first orientation and the second orientation perpendicular to each other.

In this embodiment the incisions divide the foil in rectangular or square areas. This is particularly attractive for a foil used in a solar panel with mono crystalline solar cells, such as, but not limited to, Si or GaAs crystalline solar cells, as these are often formed as square or rectangular tiles. Preferably such tiles are then placed on or in a foil with identical or almost identical areas as the tiles themselves, each tile corresponding to one area.

Preferably all mechanically interconnected areas have an identical size and outline.

It is noted that the incisions need not be straight but may show undulations or curvature. Also, using straight incisions, other forms may be realized for the areas, preferably quadrilateral areas.

In another embodiment the foil is or comprises a back-contact foil and the incisions are made in the back-contact foil.

Nowadays the use of solar cells with anode(s) and cathode(s) at one side are popular, as no shadowing of finger electrodes occurs. A back-contact foil is then used to electrically and mechanically interconnect the solar cells. A back-contact foil is typically a thin synthetic foil, such as a PET or polyimide foil with a thickness of for example 200 μm, preferably with metallization on one or both sides for electrically connecting. The metallization, preferably a patterned copper cladding, is used to form the electrical interconnections between the solar cells. The metallization can be present on one side of the back-contact foil, or on both sides. Vias can be used to connect metallization from one side to the other side. These techniques are well known from printed circuit boards (PCBs) and Flexible Circuit Boards (FCBs).

It is noted that the foil, a synthetic foil such as a PET or a polyimide foil, typical has a thickness of 200 μm or more. When deforming such a foil in a 3-D curvature, wrinkles can occur, but deforming only the much smaller mechanical interconnections greatly reduces the wrinkling.

In yet another embodiment the foil comprises thin film solar cells and the incisions are made in the thin film solar cells.

Thin film solar cells typically comprise a foil upon which a photovoltaic material is applied, for example by spraying. The photovoltaic material may be, for example, cadmium telluride (CdTe), copper indium gallium diselenide (CIGS), amorphous thin-film silicon (a-Si, TF-Si) or perovskites. By making incisions in this foil a thin film solar foil is made that can, after making the foil, be formed in 3D curved form.

In still another embodiment the foil comprises an encapsulant and the incisions are made in the encapsulant.

In this embodiment the foil is an encapsulant. Especially when the encapsulant is cured, it becomes rigid and shows less flexibility and it may become necessary to make it more flexible again by making the incisions in it.

In yet other embodiments a solar panel, a vehicle or a building integrated photovoltaic system comprises a foil according to the invention.

### BRIEF DESCRIPTION OF THE DRAWINGS

The invention is now elucidated using figures, in which identical reference signs indicate corresponding features. To that end:

FIG. 1 schematically shows a foil with incisions according to the invention, and

FIG. 2 schematically shows the foil of FIG. 1 when stretched.

### DETAILED DESCRIPTION OF THE INVENTION

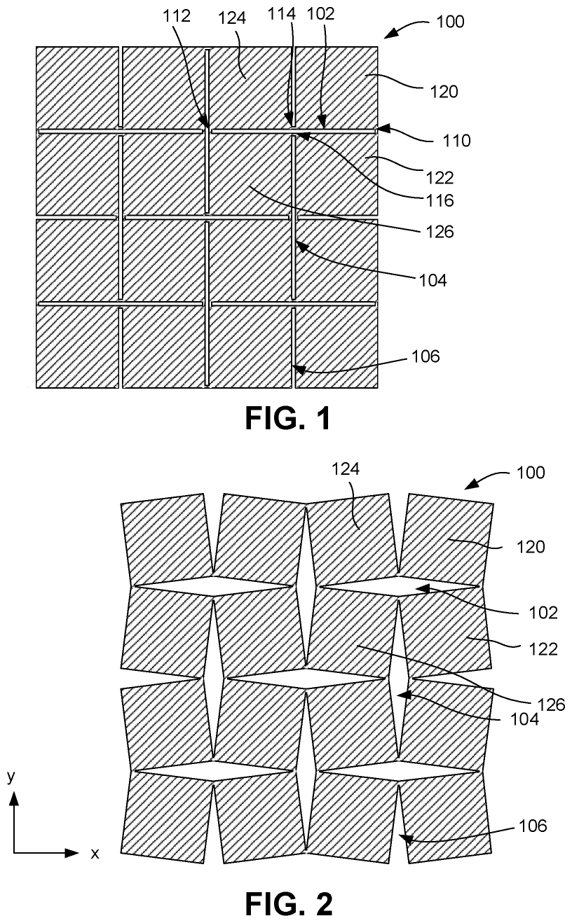

FIG. 1 schematically shows a foil with incisions according to the invention.

A foil 100 shows a multitude of incisions. Incision 102 has a first closed end 110 ending in a mechanical interconnection 110 between cells 120 and 122 and a second closed end 112 ending in a mechanical interconnection 112 between cell 124 and cell 126. The incision is bordered by a mechanical interconnection between cells 120 and 124 and also by a mechanical interconnection between cells 122 and 126. Incision 104, perpendicular to incision 102 ends at a first end at the mechanical interconnection 116, that borders incision 102.

It is noted that the foil also comprises incisions that have only one closed end, such as incision 106. These incisions end at the border of the foil. However, even when a border part of the foil does not show such single ended incision, a foil that can deform in 3D can be made, where the border will stay flat and the center portion of the foil can curve in a spherical surface.

FIG. 2 schematically shows the foil of FIG. 1 when stretched.

The foil 100 is stretched in the x-direction. Due to the stress occurring the areas slightly rotate and the incisions change shape from slits (having a surface close to zero) to diamond-shaped (rhombic) surfaces, also resulting in elongation in the y-direction. Because the elongation in the x-direction necessitates an elongation in the y-direction, the foil can be classed as an auxetic foil, that is: a foil with a negative Poisson ratio,

It is noted that the ratio between x- and y-elongation depends on the dimensions of the areas in the x- and y-direction. For square areas the ratio is 1, for rectangular areas the x-elongation is not equal to the y-elongation.

It is further noted that the incisions need not be perpendicular to each other: also other quadrilateral figures, such as a diamond-shaped (rhombic) form, are possible.

To make the incisions several well-known techniques are available, such as cutting, stamping, laser cutting or ablation, cutting using a water jet, etc. Preferable the cutting does not result in sharp endings of the incisions, as this may lead to uncontrolled propagation of the incision in the mechanical interconnection. This is best achieved by either a cutting method resulting in a rounded end, or by making an incision that ends in a small loop or curved part.

1. A foil for use with a double curved solar panel, the foil showing a multitude of incisions having two closed ends, the incisions dividing the foil in a number of mechanically interconnected areas, characterized in that the foil comprises at least a first group of incisions having a first orientation and a second group of incisions having a second orientation, each of the incisions having two closed ends, a first closed end located at a mechanical interconnection between a first cell and a second cell and a second closed end located at a mechanical interconnection between a third cell and a fourth cell, the incision bordered by a mechanical interconnection between the first cell and the third cell and bordered by a mechanical interconnection between the second cell and the fourth cell, the incisions partly having a first orientation and partly having a second orientation, the first orientation different from the second orientation.

2. The foil of claim 1 further comprising one or more incisions having only one closed end ending at a mechanical interconnection, said incisions intersecting the border of the foil.

3. The foil of claim 1 in which the incisions are straight incisions and the first orientation and the second orientation are perpendicular to each other.

4. The foil of claim 1 in which all mechanically interconnected areas have an identical size and outline.

5. The foil of claim 1 in which the foil is or comprises a back-contact foil and the incisions are made in the back-contact foil.

6. The foil of claim 1 in which at least part of the back-contact foil comprises an electrically conductive layer.

7. The foil of claim 1 in which the foil comprises thin film solar cells and the incisions are made in the thin film solar cells.

8. The foil of claim 1 in which the foil comprises an encapsulant and the incisions are made in the encapsulant.

9. A solar panel comprising a foil according to claim 1.

10. A vehicle comprising a foil according to claim 1.

11. A Building Integrated Photovoltaic system comprising a foil according to claim 1.
